(19) United States
(12) Patent Application Publication
(10) Pub. No.: US 2012/0056309 A1
(43) Pub. Date: Mar. 8, 2012

(54) SEMICONDUCTOR DEVICE WITH REDUCED HEAT-INDUCED LOSS

(75) Inventor: Youngsuk Kim, Ota-Ku (JP)

(73) Assignee: DISCO CORPORATION, Tokyo (JP)

(21) Appl. No.: 13/215,419

(22) Filed: Aug. 23, 2011

(30) Foreign Application Priority Data
Sep. 8, 2010 (JP) 2010-200565

(51) Int. Cl. H01L 29/06

(52) U.S. Cl. 257/620; 257/E29.022

(57) ABSTRACT

A semiconductor device which is capable of reducing a heat-induced loss includes a substrate and a circuit element disposed on the substrate. The substrate is of a rectangular shape with beveled surfaces on four corners thereof.

### BACKGROUND OF THE INVENTION

1. Field of the Invention

The present invention relates to a semiconductor device including a substrate and circuit elements disposed on the substrate.

2. Description of the Related Art

According to a process of fabricating semiconductor devices, division lines are formed in a grid pattern on a wafer made of silicon, for example, and circuit elements such as ICs, LSI circuits, or the like are formed in areas defined by the division lines. Thereafter, the wafer with the circuit elements formed thereon is divided along the division lines into the semiconductor devices. The divided semiconductor devices will be used in a wide range of electric appliances.

The electric appliances include semiconductor devices called power devices, such as transistors, diodes, etc., for converting supplied electric energy into kinetic energy, thermal energy, optical energy, etc. In recent years, it has become increasingly important to reduce a power loss caused by power devices for various reasons including attempts to turn electric appliances into an energy saver. Research and development efforts are being made to fabricate power devices of materials such as GaN (Gallium Nitride) and SiC (Silicon Carbide) which are of a high withstand pressure and a low loss, are operable at high temperatures, and have a wide band gap, instead of silicon used heretofore (see JP-T-2002-519851).

### SUMMARY OF THE INVENTION

In operation, higher voltages are applied to power devices made of materials such as GaN, SiC, etc. having a wide band gap, than to power devices made of silicon used heretofore. Since existing power devices which are divided along division lines in a grid pattern are of a rectangular shape, an electric field tends to concentrate on the corners of the power devices. When the circuit elements of the power devices are heated due to an electric field concentration, they are liable to cause a reduction in the electron mobility and a reduction in the current, resulting in a reduction in the operating speed of the circuit devices.

For example, the intensity E of an electric field on the surface of a conductive sphere having a radius R which carries an electric charge Q can be calculated according to the following equations:

E=Q/(4πε₀R²) (1)

V=Q/(4πε₀R) (2)

where V represents the potential of the conductive sphere, and ε₀ the dielectric constant in vacuum.

From the equations (1), (2), E=V/R. Therefore, it can be seen that as the radius R is greater, the intensity E of the electric field is smaller.

It is an object of the present invention to provide a semiconductor device which is capable of reducing a heat-induced loss.

In accordance with an aspect of the present invention, there is provided a semiconductor device including a substrate and a circuit element disposed on the substrate, wherein the substrate is of a rectangular shape with beveled surfaces on four corners thereof. Preferably, the circuit element includes a power circuit element.

Since the four corners of the rectangular substrate have the beveled surfaces, when a high voltage is applied to the semiconductor device of the present invention, no electric field concentrates on the corners, and the semiconductor device causes a reduced heat-induced loss. Inasmuch as the heat-induced loss of the semiconductor device is reduced, the semiconductor device can be packaged in a small size, and can be used in a wide range of applications as a power semiconductor device.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view, partly in block form, a laser beam processing apparatus;

FIG. 2 is a block diagram of a laser beam generating unit;

FIG. 3 is a perspective view illustrative of a processing method according to a first embodiment of the present invention;

FIG. 4 is a plan view of a semiconductor wafer processed by the processing method according to the first embodiment;

FIG. 5A is a perspective view of a semiconductor device according to the first embodiment;

FIG. 5B is a plan view of the semiconductor device according to the first embodiment;

FIG. 6 is a perspective view illustrative of a processing method according to a second embodiment of the present invention;

FIG. 7 is a perspective view illustrative of a processing method according to the second embodiment of the present invention;

FIG. 8A is a perspective view of a semiconductor device according to the second embodiment;

FIG. 8B is a plan view of the semiconductor device according to the second embodiment; and

FIG. 9 is a plan view of a semiconductor device according to a third embodiment of the present invention.

### DETAILED DESCRIPTION OF THE PREFERRED EMBODIMENTS

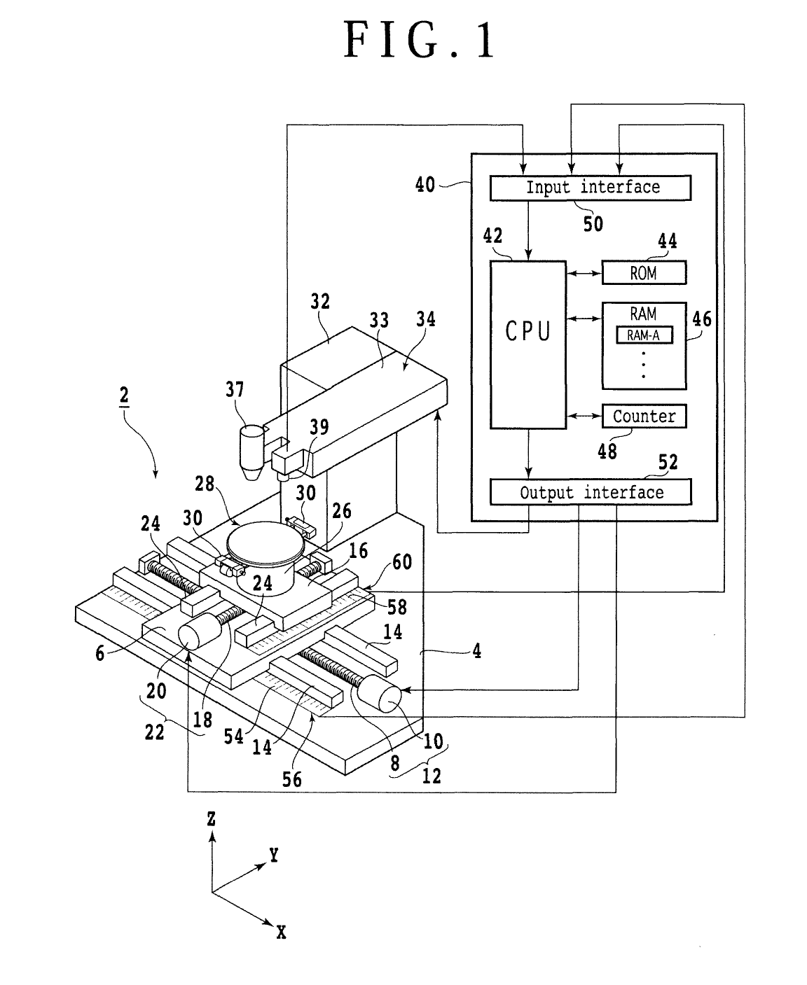

Preferred embodiments of the present invention will be described in detail below with reference to the drawings. Like or corresponding parts are denoted by like or corresponding reference characters throughout views. FIG. 1 is a perspective view, partly in block form, a laser beam processing apparatus 2 which is suitable for carrying out processing methods according to the present invention. As shown in FIG. 1, the laser beam processing apparatus 2 includes a stationary base 4 and a first slide block 6 slidably mounted on the stationary base 4 for sliding movement in X-axis directions. The first slide block 6 is movable in processing feed directions, i.e., the X-axis directions, along a pair of guide rails 14 on the stationary base 4 by a processing feed mechanism 12 which includes a ball screw 8 and a stepping motor 10 on the stationary base 4.

The laser beam processing apparatus 2 also includes a second slide block 16 slidably mounted on the first slide block 6 for sliding movement in Y-axis directions. The second slide block 16 is movable in indexing feed directions, i.e., the Y-axis directions, along a pair of guide rails 24 on the first slide block 6 by an indexing feed mechanism 22 which includes a ball screw 18 and a stepping motor 20 on the first slide block 6. The laser beam processing apparatus 2 further includes a chuck table 28 supported on the second slide block 16 by a hollow cylindrical support member 26. The chuck table 28 is angularly movable through given angular intervals about its own vertical axis on the second slide block 16. The chuck table 28 is movable in the X-axis directions and the Y-axis directions by the processing feed mechanism 12 and the indexing feed mechanism 22. The chuck table 28 includes a clamp 30 for clamping a semiconductor wafer that is attracted to the chuck table 28 under suction.

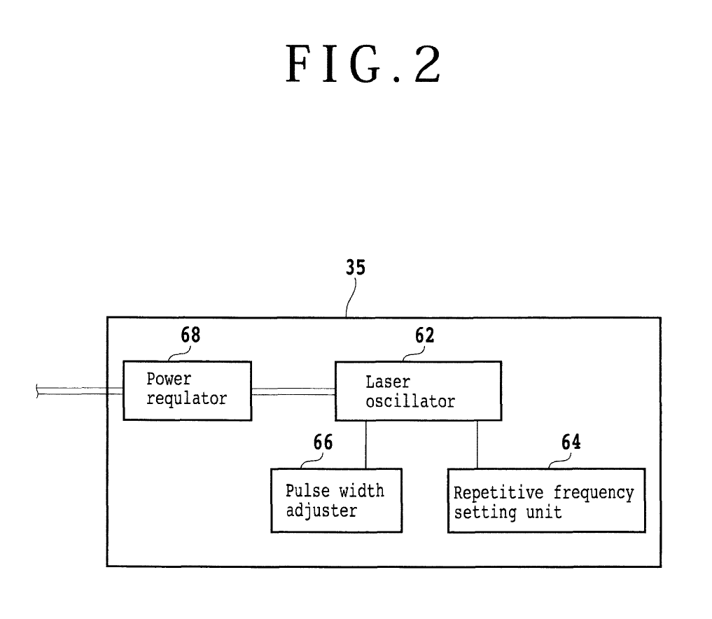

A column 32 is vertically mounted on the stationary base 4 adjacent to the first slide block 6, the second slide block 16, and the chuck table 28. A laser beam applying unit 34 is attached to an upper end of the column 32. The laser beam applying unit 34 includes a laser beam generating unit 35 (see FIG. 2) housed in a casing 33, and a beam condenser 37 mounted on an end of the casing 33. As shown in FIG. 2, the laser beam generating unit 35 includes a laser oscillator 62 for emitting a YAG laser beam or a YVO4 laser beam, a repetitive frequency setting unit 64, a pulse width adjuster 66, and a power regulator 68.

The end of the casing 33 also supports an image capturing unit 39, aligned with the beam condenser 37 along the X-axis directions, for detecting an area on a semiconductor device to be processed by a laser beam. The image capturing unit 39 includes an image capturing device such as a CCD or the like for capturing an image of the area on the semiconductor device with visible light. The image capturing unit 39 also includes an infrared image capturing system which includes an infrared radiation applying unit for applying an infrared radiation to the semiconductor wafer, an optical system for capturing the infrared radiation applied by the infrared radiation applying unit, and an infrared image capturing device such as an infrared CCD or the like for outputting an electric signal representative of the infrared radiation captured by the optical system. The electric signal output by the infrared image capturing device is transmitted as an image signal representative of the infrared radiation to a controller 40 (see FIG. 1).

The controller 40 includes a computer including a central processing unit (CPU) 42 for performing arithmetic operations according to control programs, a read-only memory (ROM) 44 for storing the control programs, etc., a random-access memory (RAM) 46 for storing results of the arithmetic operations, a counter 48, an input interface 50, and an output interface 52.

A processing feed distance detector 56 includes a linear scale 54 disposed on the stationary base 4 along one of the guide rails 14, and a reading head, not shown, mounted on the first slide block 6. The processing feed distance detector 56 supplies a detected signal to the input interface 50 of the controller 40. An indexing feed distance detector 60 includes a linear scale 58 disposed on the first slide block 6 along one of the guide rails 24, and a reading head, not shown, mounted on the second slide block 16. The indexing feed distance detector 60 supplies a detected signal to the input interface 50 of the controller 40. The image capturing unit 39 also supplies an image signal to the input interface 50 of the controller 40. The output interface 52 of the controller 40 outputs control signals to the stepping motor 10, the stepping motor 20, and the laser beam applying unit 34.

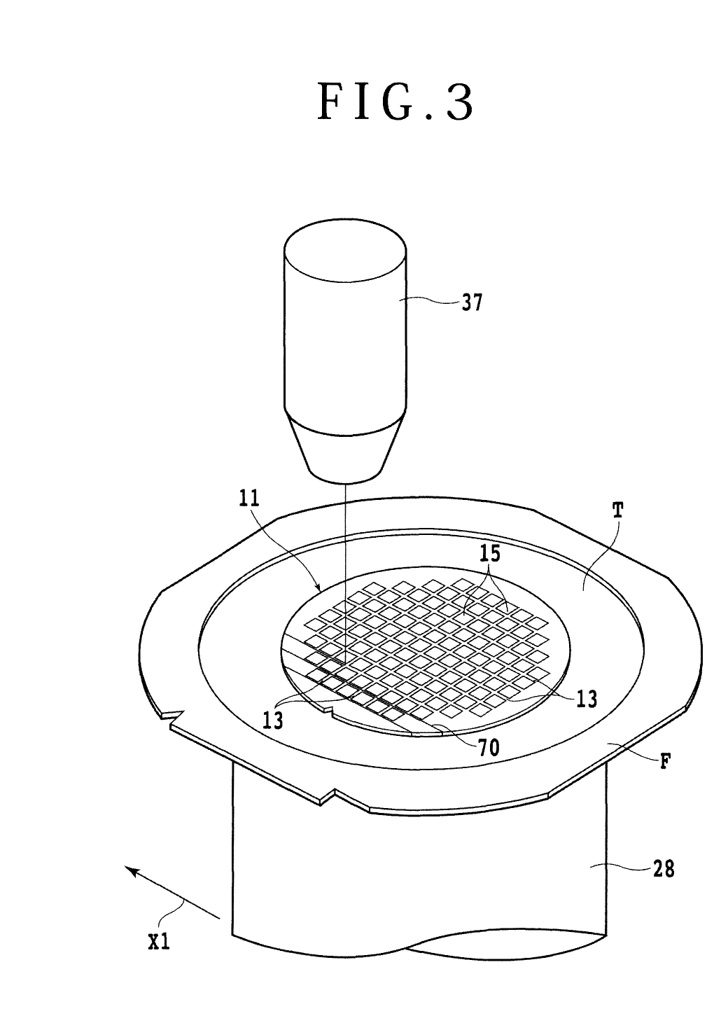

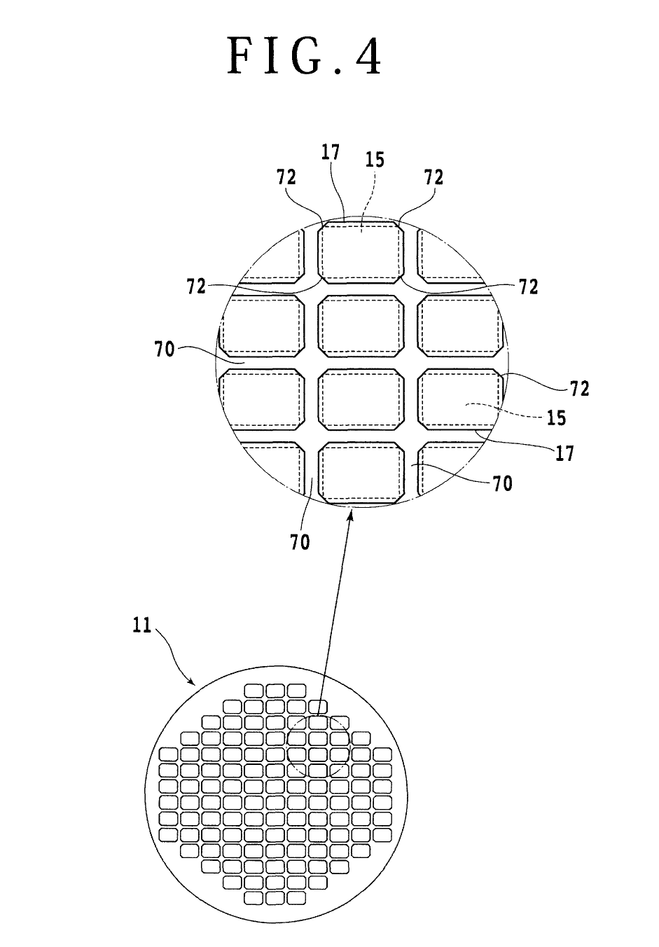

A processing method according to a first embodiment of the present invention, which is carried out by the laser beam processing apparatus 2, will be described below with reference to FIG. 3. A semiconductor wafer 11, which is to be processed by the laser beam processing apparatus 2, is made of SiC (silicon carbide) and has a plurality of division lines (streets) 13 arranged on its surface in a grid pattern. Circuit elements 15 such as power circuit elements, etc. are disposed in respective rectangular areas defined by the streets 13, making up semiconductor devices 17 (see FIG. 4). The semiconductor wafer 11 is applied to a circular dicing tape T, which is an adhesive tape, that has an outer circumferential region applied to an annular frame F. The semiconductor wafer 11 is thus supported on the annular frame F by the dicing tape T.

In the processing method according to the first embodiment, as shown in FIG. 3, the semiconductor wafer 11 is placed on the chuck table 28 of the laser beam processing apparatus 2, and attracted to the chuck table 28 under suction through the dicing tape T. Although not shown in FIG. 3, the annular frame F is clamped in position by the clamp 30. The chuck table 28 with the semiconductor wafer 11 attracted thereto under suction is positioned immediately below the image capturing unit 39 by the processing feed mechanism 12. The image capturing unit 39 then performs an alignment process for detecting an area of the semiconductor wafer 11 to be processed by a laser beam.

The alignment process will be described in detail below. The image capturing unit 39 and the controller 40 perform an image processing sequence such as a pattern matching sequence for positioning one, at a time, of the division lines 13 which extends along a first direction on the semiconductor wafer 11 in alignment with the beam condenser 37 of the laser beam applying unit 34 which applies a laser beam to the semiconductor wafer 11 along the division line 13, thereby aligning the laser beam spot on the semiconductor wafer 11 with the division line 13. The image capturing unit 39 and the controller 40 also perform an image processing sequence for positioning one, at a time, of the division lines 13 which extends along a second direction, perpendicular to the first direction, on the semiconductor wafer 11 in alignment with the beam condenser 37 of the laser beam applying unit 34, thereby aligning the laser beam spot on the semiconductor wafer 11 with the division line 13.

After the alignment process, the laser beam applying unit 34 continuously applies a laser beam having a wavelength which is absorbable by the semiconductor wafer 11 to the surface of the semiconductor wafer 11 along one of the division lines 13 which extend along the first direction while the chuck table 28 is being moved in the direction indicated by the arrow X1, for example, thereby forming a laser-processed groove 70 along the division line 13 by way of abrasion. The laser-processed groove 70 should preferably have a depth across the full thickness of the semiconductor wafer 11, so that the semiconductor wafer 11 is fully cut along the laser-processed groove 70. The laser beam applying unit 34 also continuously applies a laser beam to the semiconductor wafer 11 successively along the division lines 13 which extend along the first direction, thereby forming laser-processed grooves 70 along the division lines 13. Thereafter, the chuck table 28 is turned about its own vertical axis through 90 degrees. Then, the laser beam applying unit 34 applies the laser beam to the semiconductor wafer 11 successively along all the division lines 13 which extend along the second direction, thereby forming laser-processed grooves 70 along the division lines 13.

Then, the chuck table 28 is turned about its own vertical axis through 45 degrees, and the laser beam applying unit 34 intermittently applies a laser beam to the semiconductor wafer 11 to cut off corners of the semiconductor devices 17 by about 100 μm, producing cut-off surfaces 72. The circuit elements 15 are patterned such that the corners of the semiconductor devices 17 which have been cut off are free of any circuit elements. The laser beam applying unit 34 intermittently applies the laser beam to corners of the semiconductor devices 17 while the semiconductor wafer 11 is being fed at a constant processing feed speed. After diagonally opposite corners of the semiconductor devices 17 are cut off to form cut-off surfaces 72, the chuck table 28 is turned about its own vertical axis through 90 degrees, and the laser beam applying unit 34 intermittently applies a laser beam to the semiconductor wafer 11 to cut off other diagonally opposite corners of the semiconductor devices 17, producing cut-off surfaces 72.

The laser beam is applied to produce the laser-processed grooves 70 and the laser beam is intermittently applied to produce the cut-off surfaces under the following conditions:

Light source: LD-pumped Q switch Nd:YAG pulse laser

Wavelength: 355 nm (YAG laser third harmonic generation)

Repetitive frequency: 10 kHz

Average output: 7 W

Feed speed: 50 mm/second

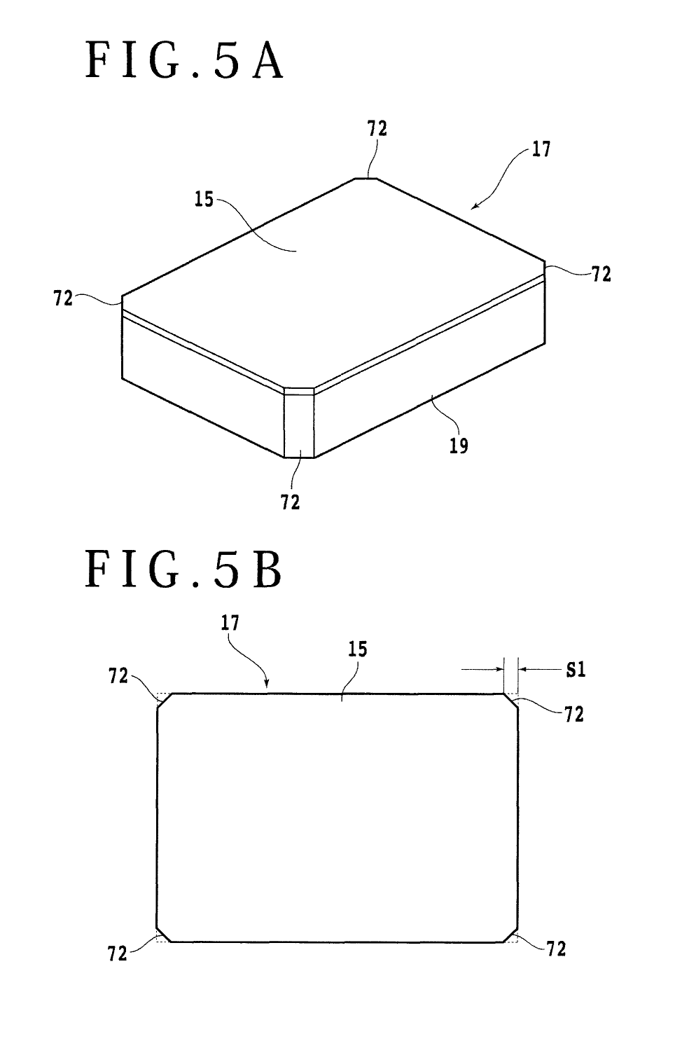

FIG. 4 is a plan view of the semiconductor wafer 11 processed by the processing method according to the first embodiment. As shown in FIG. 4, the processed semiconductor wafer 11 includes the laser-processed grooves 70 formed along the division lines 13 by the continuously applied laser beam and the semiconductor devices 17 with the cut-off surfaces 72 formed on their corners by the intermittently applied laser beam. FIG. 5A is a perspective view of each of the semiconductor devices 17 according to the first embodiment, and FIG. 5B is a plan view of the semiconductor device 17 according to the first embodiment. As shown in FIGS. 5A and 5B, the semiconductor device 17 includes a substrate 19 made of SiC, GaN, or the like and a circuit element 15 disposed on the substrate 19, with cut-off surfaces 72 on four corners thereof. In FIG. 5B, each of both sides of each of the corners that have been cut off have a length S1 which needs to be of 10 μm or greater. In the present embodiment, the length S1 is of 100 μm.

In the present embodiment, the laser-processed grooves 70 are formed along the division lines 13 to divide the semiconductor wafer 11 by the laser beam processing apparatus 2. Alternatively, the semiconductor wafer 11 may be divided along the division lines 13 by a dicing apparatus, and the corners of the semiconductor devices 17 may be cut off by the intermittent application of the laser beam generated by the laser beam processing apparatus 2.

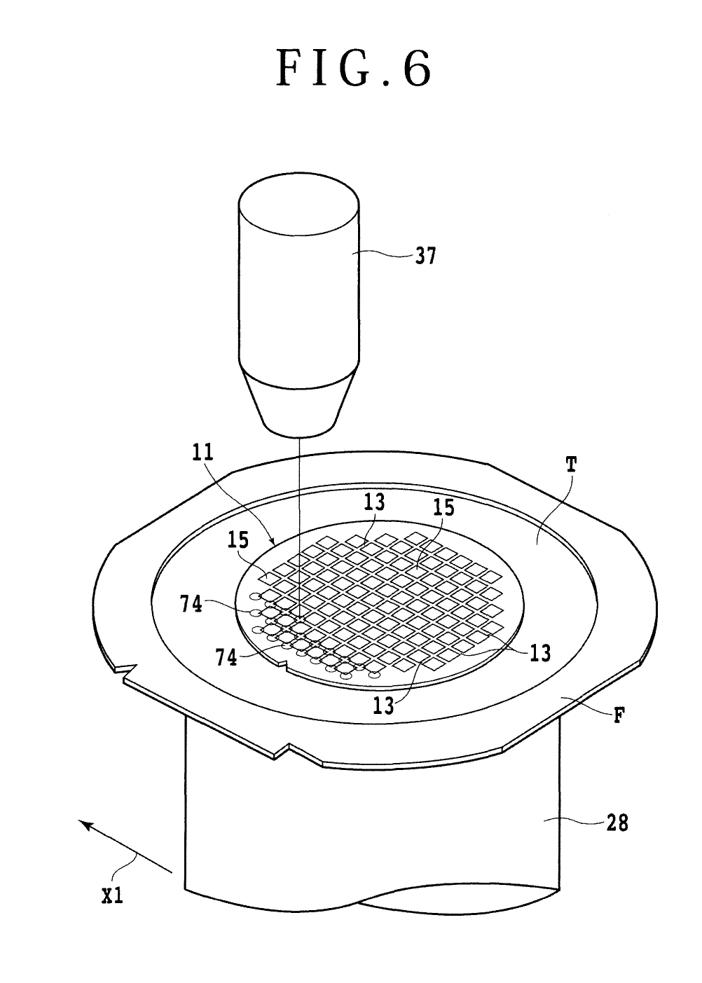

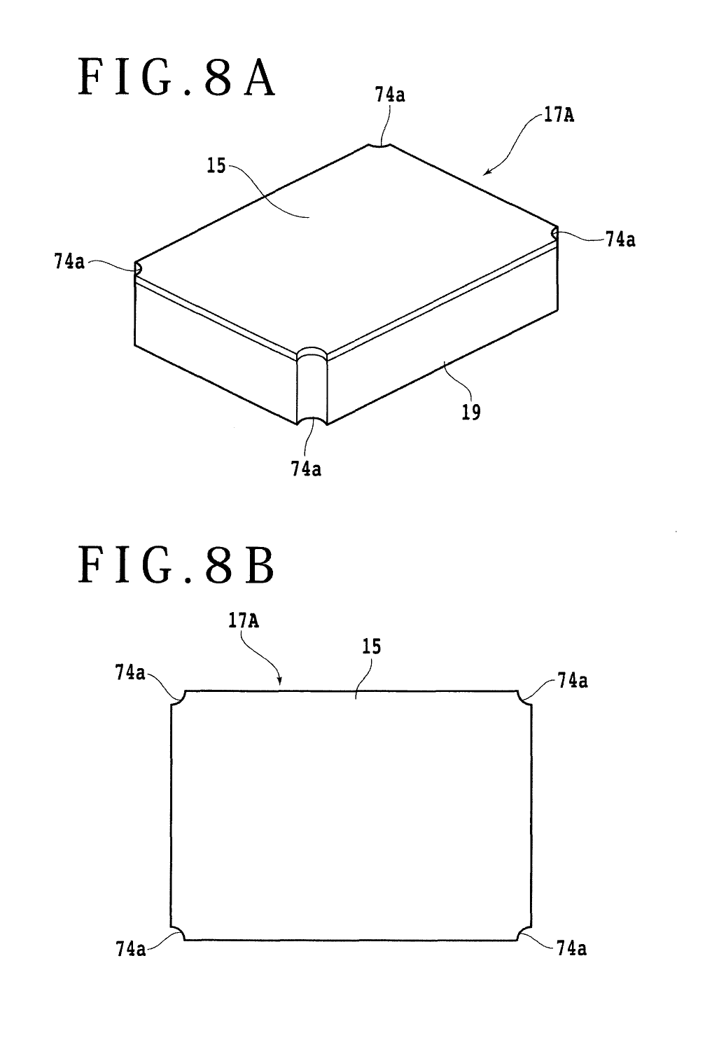

A processing method according to a second embodiment of the present invention will be described below with reference to FIGS. 6 through 8B. As shown in FIG. 6, the chuck table 28 of the laser beam processing apparatus 2 holds the semiconductor wafer 11 through the circular dicing tape T. The beam condenser 37 applies a laser beam having a wavelength which is absorbable by the semiconductor wafer 11 to a point of intersection between two perpendicular division lines 13 of all the division lines 13 that are arranged in a grid pattern on the surface of the semiconductor wafer 11, thereby forming a small hole 74 through the semiconductor wafer 11 at the point of intersection. The small hole 74 has a diameter large enough to include the corners of the rectangular areas in which the circuit elements 15 are disposed, around the point of intersection, so that arcuately beveled surfaces 74a (see FIGS. 8A and 8B) are formed in the respective corners of the rectangular areas.

The applied laser beam has a diameter of about 20 μm. Therefore, at the same time that the laser beam is applied to the point of intersection between the two perpendicular division lines 13, the chuck table 28 is moved at controlled rates along the X-axis directions and the Y-axis directions to form the small hole 74. When the formation of the small hole 74 is completed, the chuck table 28 is moved in the direction indicated by the arrow X1 by the pitch of the division lines 13, and a small hole 74 is formed at a next point of intersection between two perpendicular division lines 13.

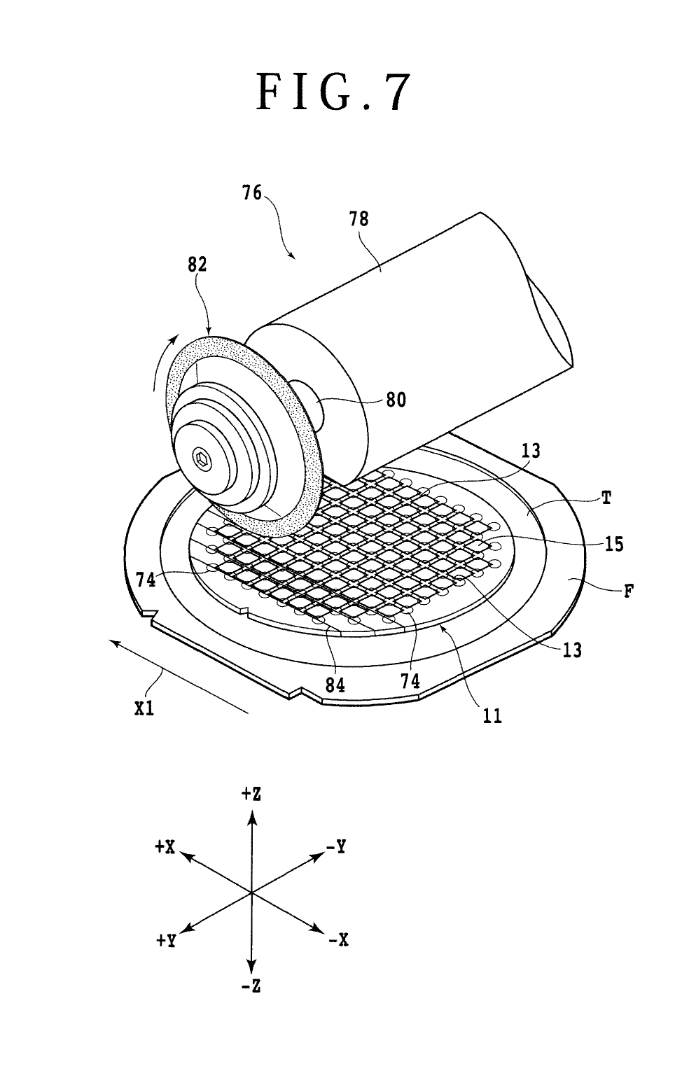

After the small holes 74 have been formed at all the points of intersection between the perpendicular division lines 13 is completed, the semiconductor wafer 11 is divided into individual semiconductor devices 17A (see FIGS. 8A and 8B) by a dicing process carried out by a cutting apparatus. The dicing process will be described below with reference to FIG. 7. In FIGS. 6 and 7, the width of the division lines 13 and the size of the small holes 74 are shown as exaggerated. In FIG. 7, the cutting apparatus includes a cutting unit 76 having a spindle 80 rotatably mounted in a spindle housing 78 and a cutting blade 82 mounted on the distal end of the spindle 80.

A chuck table, not shown, of the cutting apparatus holds under suction the semiconductor wafer 11 through the circular dicing tape T. Then, an alignment process is performed to detect division lines 13 along which the semiconductor wafer 11 is to be cut or diced. After the alignment process, while the cutting blade 82 is rotated at a high speed of 30,000 rpm, for example, the cutting blade 82 cuts into one of the division lines 13 which extends along the first direction, and the chuck table is fed in the X1 direction to form a cut groove 84 in the semiconductor wafer 11 down to the citing tape T along the division line 13.

The cutting unit 76 is fed in the Y-axis directions, and cut grooves 84 are formed in the semiconductor wafer 11 along all the division lines 13 which extend along the first direction. Then, the chuck table is turned through 90 degrees, and a cut groove 84 is formed in the semiconductor wafer 11 along one of the division lines 13 which extend along the second direction perpendicular to the first direction. When the formation of cut grooves 84 along all the division lines 13 which extend along the second direction is completed, the semiconductor wafer 11 is divided into individual semiconductor devices 17A shown in FIGS. 8A and 8B. Each of the individual semiconductor devices 17A thus fabricated has arcuately beveled surfaces 74a on its four corners.

The semiconductor devices 17A are preferably power devices whose substrate 19 is made of SiC or GaN, and each have arcuately beveled surfaces 74a on its four corners. When a high voltage is applied to the semiconductor devices 17A, no electric field concentrates on the corners thereof, and hence the semiconductor devices 17A cause a reduced heat-induced loss.

A modification of the processing method according to the second embodiment will be described below. According to the modification, instead of cutting the semiconductor wafer according to the dicing process performed by the cutting apparatus, the semiconductor wafer is grooved by a laser beam applied thereto or a modified layer is developed in the semiconductor wafer by a laser beam applied thereto, and then the semiconductor wafer 11 is divided along the division lines 13 into individual semiconductor devices 17A by a breaking apparatus.

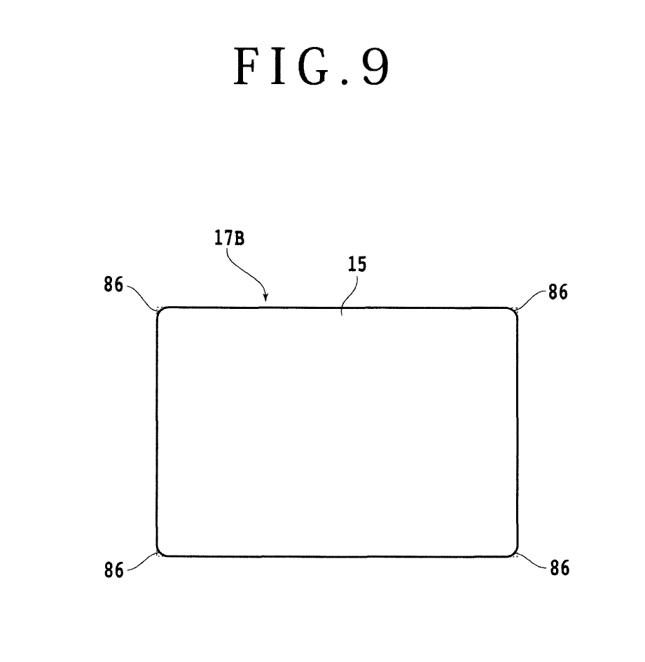

FIG. 9 is a plan view of a semiconductor device 17B according to a third embodiment of the present invention. As shown in FIG. 9, the semiconductor device 17B according to the third embodiment has round beveled surfaces 86 at its four corners. The semiconductor device 17B with the round beveled surfaces 86 offers the same advantages as the semiconductor devices 17, 17A according to the first and second embodiments described above.

In the above embodiments, the semiconductor wafer 11 is made of SiC. However, the present invention is not limited to semiconductor wafers made of SiC, but is also applicable to a semiconductor wafer made of GaN or a semiconductor wafer including a substrate of sapphire and a GaN layer deposited thereon by epitaxial growth.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A semiconductor device comprising:
a substrate; and
a circuit element disposed on said substrate;
wherein said substrate is of a rectangular shape with beveled surfaces on four corners thereof.

2. The semiconductor device according to claim 1, wherein said circuit element comprises a power circuit element.
